(19) United States
(12) Patent Application Publication
(10) Pub. No.: US 2026/0173910 A1
(43) Pub. Date: Jun. 18, 2026

(54) ELECTRONIC DEVICE AND MANUFACTURING METHOD THEREOF

(71) Applicant: Innolux Corporation, Miaoli County (TW)

(72) Inventors: Po-Yun Hsu, Miaoli County (TW); Ju-Li Wang, Miaoli County (TW); Ker-Yih Kao, Miaoli County (TW)

(73) Assignee: Innolux Corporation, Miaoli County (TW)

(21) Appl. No.: 19/390,655

(22) Filed: Nov. 16, 2025

Related U.S. Application Data
(60) Provisional application No. 63/733,450, filed on Dec. 13, 2024.

(30) Foreign Application Priority Data
Jun. 27, 2025 (CN) 202510882009.8

(51) Int. Cl. H01L 23/538; H01L 21/48; H01L 23/00; H01L 23/15; H01L 25/065

(52) U.S. Cl. CPC H10W 70/611; H10W 70/095; H10W 70/635; H10W 90/00; H10W 99/00; H10W 70/692; H10W 74/15; H10W 90/724; H10W 90/733; H10W 90/734

(57) ABSTRACT

Provided is a manufacturing method of an electronic device including the following steps. A substrate is provided, where the substrate has a first surface and a second surface opposite to each other. A through hole penetrating the substrate is formed. A build-up structure on the first surface and the second surface of the substrate is formed. The build-up structure disposed on the first surface and the second surface is simultaneously cut, so that the build-up structure forms a first groove and a second groove respectively. An electronic device is also provided.

### CROSS-REFERENCE TO RELATED APPLICATION

This application claims the priority benefits of U.S. provisional application Ser. No. 63/733,450, filed on Dec. 13, 2024 and China application serial no. 202510882009.8, filed on Jun. 27, 2025. The entirety of each of the above-mentioned patent applications is hereby incorporated by reference herein and made a part of this specification.

### BACKGROUND

### Technical Field

The disclosure relates to an electronic device, and in particular to a design of an electronic device having a through hole substrate and a manufacturing method thereof.

### Related Art

In a process of manufacturing an electronic device, components located on both sides of a mother substrate have different physical properties (for example, thermal expansion coefficients). Therefore, the mother substrate of the electronic device is prone to warping due to stress mismatch. In addition, when the mother substrate is cut, the mother substrate is also prone to cracking due to stress mismatch, which results in a decrease in yield and/or reliability of the finally formed electronic device.

### SUMMARY

The disclosure is directed to a manufacturing method of an electronic device, which may improve yield and/or reliability of the manufactured electronic device.

According to some embodiments of the disclosure, a manufacturing method of an electronic device includes the following steps. A substrate is provided. A through hole penetrating the substrate is formed. A build-up structure is formed on both sides of the substrate. The build-up structure is simultaneously cut to expose a partial surface of the substrate.

The disclosure is directed to an electronic device having improved yield and/or reliability.

According to some embodiments of the disclosure, an electronic device includes a substrate, a through hole, a connection element, and a build-up structure. The through hole penetrates the substrate. The connection element is disposed in the through hole. The build-up structure is disposed on both sides of the substrate and is electrically connected to the connection element. Surfaces located on the both sides of the substrate are rough surfaces, and the build-up structures expose at least one part of the rough surfaces.

### BRIEF DESCRIPTION OF THE DRAWINGS

FIG. 1 is a schematic view of an intermediate process of a manufacturing method of an electronic device according to an embodiment of the disclosure.

FIG. 2 is a schematic view of an intermediate process of a manufacturing method of an electronic device according to an embodiment of the disclosure.

FIG. 3 is a schematic view of an intermediate process of a manufacturing method of an electronic device according to another embodiment of the disclosure.

FIG. 4 is a schematic cross-sectional view of an electronic device according to an embodiment of the disclosure.

FIG. 5 is a flow chart of a manufacturing method of an electronic device according to an embodiment of the disclosure.

FIG. 6 is a schematic cross-sectional view of an electronic device according to another embodiment of the disclosure.

### DESCRIPTION OF THE EMBODIMENTS

Reference will now be made in detail to exemplary embodiments of the disclosure, examples of the exemplary embodiments are illustrated in the accompanying drawings. Wherever possible, the same reference numerals are used in the drawings and the description to refer to the same or like parts.

The disclosure may be understood through reference to the following detailed description in conjunction with the accompanying drawings. It should be noted that, for ease of understanding by readers and for simplicity of the drawings, multiple drawings in the disclosure only illustrate a part of the electronic device, and specific elements in the drawings are not drawn to actual scale. In addition, the number and sizes of each element in the drawings are merely illustrative and are not intended to limit the scope of the disclosure.

Certain terms are used throughout the disclosure specification and the appended claims to refer to specific elements. Those skilled in the art should understand that electronic device manufacturers may refer to the same element by different names. This document does not intend to distinguish between elements that have the same function but different names. In the following specification and claims, terms such as “include”, “contain”, and “have” are open-ended terms and should therefore be interpreted as meaning “including but not limited to . . . ”. Accordingly, when used in the description of the disclosure, the terms such as “include”, “contain”, and/or “have” specify the presence of corresponding features, regions, steps, operations, and/or components, but do not exclude the presence of one or more corresponding features, regions, steps, operations, and/or components.

Directional terms such as “upper”, “lower”, “front”, “rear”, “left”, and “right” mentioned in the disclosure are only directions with reference to the drawings. Therefore, the used directional terms are used to illustrate, but not to limit, the disclosure. In the drawings, each drawing illustrates the general characteristics of a method, a structure, and/or a material used in a specific embodiment. However, the drawings should not be construed to define or limit the scope or nature covered by the embodiments. For example, the relative sizes, thicknesses, and positions of various film layers, regions, and/or structures may be reduced or enlarged for clarity.

When a corresponding component (such as a layer or region) is referred to as being “on another component”, it may be directly on the other component, or there may be other components present between the two. On the other hand, when a component is referred to as being “directly on another component”, no components exist between the two. Additionally, when a component is referred to as being “on another component”, the two have a vertical relationship in a top view direction, and this component may be above or below the other component, with this vertical relationship depending on the orientation of the device.

The terms such as “equal to”, “same”, “substantially”, or “approximately” are generally interpreted as being within 20% of a given value or range, or interpreted as being within 10%, 1%, or 0.5% of a given value or range.

Ordinal numbers such as “first” and “second” used in the specification and claims are configured to modify elements, and do not inherently imply or represent that the element(s) have any preceding ordinal numbers, nor do the ordinal numbers represent the order of one element relative to another element, or the order in manufacturing methods. The use of the ordinal numbers is solely to enable clear distinction between an element with a certain designation and another element with the same designation. The same terminology may not be used in the claims and specification; accordingly, a first component in the specification may be a second component in the claims.

It should be noted that the following embodiments may substitute, reorganize, and mix features from several different embodiments to complete other embodiments without departing from the spirit of the disclosure.

The electrical connections or couplings described in the disclosure may refer to direct connections or indirect connections. In the case of direct connections, the terminals of elements on two circuits are directly connected or connected to each other through a conductive wire segment. In the case of indirect connections, switches, diodes, capacitors, inductors, other suitable elements, or combinations of the aforementioned elements exist between the terminals of components on two circuits, but are not limited thereto.

In the disclosure, the measurement methods for thickness, length, width, and area may be obtained by measuring cross-sectional images in an electron microscope, an optical microscope measurement, an α-step, an ellipsometer, but is not limited thereto. Additionally, any two values or directions used for comparison may have certain errors. If a first value is equal to a second value, it implies that there may be approximately 10% error between the first value and the second value; if a first direction is perpendicular to a second direction, the angle between the first direction and the second direction may be between 80 degrees and 100 degrees; and if a first direction is parallel to a second direction, an angle between the first direction and the second direction may be between 0 degrees and 10 degrees. Furthermore, the terms such as “a given range is from a first value to a second value” and “a given range falls within the range from a first value to a second value” indicate that the given range includes the first value, the second value, and other values between the two.

In the disclosure, the term “one element surrounds another element” may refer to the one element at least contacting one side surface of the another element in a cross-sectional view.

The manufacturing process of the electronic device of the disclosure may be provided, for example, through a wafer-level package (WLP) process or a panel-level package (PLP) process, which may be a chip first process or chip last RDL first process.

The electronic device described in the disclosure may be applied to a high-speed computing module, a power module, a semiconductor packaging device, a display device, a light-emitting device, a backlight device, an antenna devices, a sensing device, or a splicing device, but is not limited thereto. The electronic device includes rollable, bendable, or flexible electronic devices, but is not limited thereto. It should be noted that the electronic device may be any combination of the foregoing, but is not limited thereto. The electronic device may have peripheral systems such as a driving system, a control system, a light source system to support a display device, an antenna device, a wearable device (including, for example, augmented reality or virtual reality), a vehicle-mounted device (including, for example, an automobile windshield), or a splicing device. The electronic device may include an electronic unit, where an electronic element may include a passive element and an active elements, such as a capacitor, a resistor, an inductor, a diode, a transistor, and a sensor. It should be noted that the electronic device of the disclosure may be various combinations of the aforementioned devices, but is not limited thereto. A manufacturing method of the packaging device in the disclosure may be applied to, for example, a WLP process or a PLP process. The WLP process or the PLP process may include a chip-first process or a chip last process, but is not limited thereto. The electronic device may include a packaging device such as a high bandwidth memory (HBM) package, a system on a chip (SoC), a system in a package (SiP), an antenna in package (AiP), a co-packaged optics (CPO), or various combinations of the aforementioned devices, but is not limited thereto.

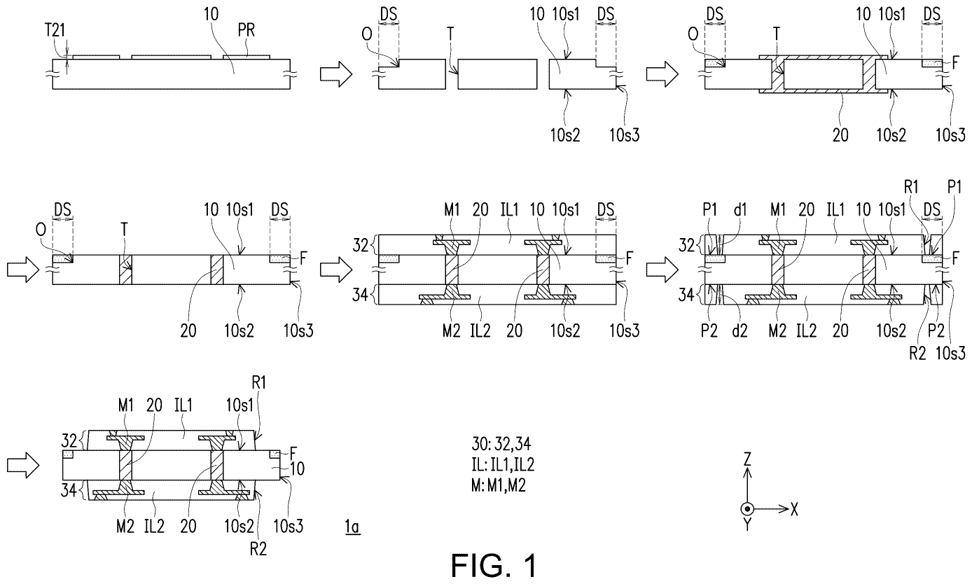

FIG. 1 is a schematic view of an intermediate process of a manufacturing method of an electronic device according to an embodiment of the disclosure.

Please refer to FIG. 1. According to some embodiments, an electronic device 1a may be formed by performing the following steps, but the disclosure is not limited thereto.

Performing step (1): a substrate 10 is provided.

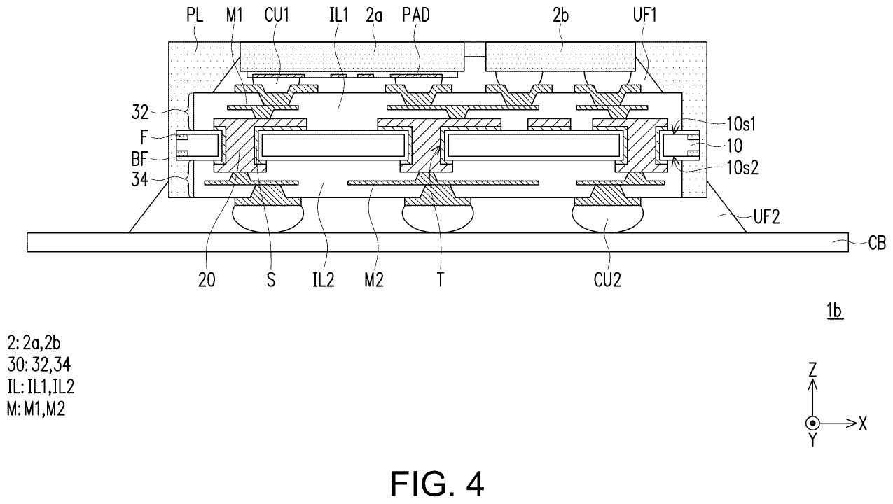

A material of the substrate 10 may include, for example, a suitable ceramic material. The substrate 10 may include a glass substrate, a silicon-containing material, an optical layer, an acrylic plate, a semiconductor structure substrate, combinations thereof, or other transparent materials, and may have certain properties of stiffness and insulation. That is, the stiffness of the substrate 10 may be greater than stiffness of a build-up structure (such as a build-up structure 32 shown in FIG. 4) formed thereon. For example, the stiffness of the substrate 10 is greater than stiffness of an insulation layer of the build-up structure, so that a substrate SB may reduce warpage when being configured to carry the build-up structure, but is not limited thereto. The “stiffness” referred to in the disclosure may be detected through a universal testing machine (UTM). For example, the material of the substrate 10 includes a transparent material, glass, alkali-free glass, quartz glass, but the disclosure is not limited thereto. According to some embodiments, the substrate 10 is a glass substrate, but the disclosure is not limited thereto.

In some embodiments, the substrate 10 may be formed by stacking multiple sub-substrates, and materials of the sub-substrates may be the same or different from each other, thermal expansion coefficients thereof may be the same or different from each other, thicknesses thereof may be the same or different from each other, and stiffness thereof may be the same or different from each other. For example, the substrate 10 may be formed by performing a heating process, a pressurizing process, a bonding process, other suitable processes, or combinations thereof on two or more sub-substrates (not shown) with different thermal expansion coefficients, but the disclosure is not limited thereto.

Performing step (2): a through hole T penetrating the substrate 10 is formed.

In some embodiments, the through hole T may be formed by performing a laser modification process, a drilling process, an etching process, or combinations thereof, but the disclosure is not limited thereto. In other embodiments, sub-substrates which are already formed with through holes may be stacked to form the substrate 10 having the through hole T. According to some embodiments, the through hole T penetrates two opposite surfaces of the substrate 10, that is, the through hole T penetrates a surface 10s1 and a surface 10s2 of the substrate 10, and a sidewall of the through hole T may be respectively connected to the surface 10s1 and the surface 10s2. According to some embodiments, the process of forming the through hole T further includes forming an opening O in an edge zone DS. The edge zone DS may be regarded as a dicing street, and the opening O does not penetrate the substrate 10. Although FIG. 1 only shows that the surface 10s1 of the substrate 10 has the opening O, the surface 10s2 of the substrate 10 may also have an opening O.

It is worth noting that although FIG. 1 shows that covering the substrate 10 by using a mask pattern PR and forming the through hole T and the opening O by performing the laser modification process on the substrate 10, the disclosure is not limited thereto. In some embodiments, the mask pattern PR may be formed by performing a suitable coating process, an exposure process, and a development process sequentially, but the disclosure is not limited thereto. The mask pattern PR is made of, for example, a material that may absorb laser, that is, the mask pattern PR may serve as a laser absorption layer and/or a laser blocking layer, and laser may not penetrate the mask pattern PR. In some embodiments, a transmittance of the mask pattern PR for light with a wavelength of 280 nm to 400 nm is less than or equal to 10%, but is not limited thereto. A thickness T21 of the mask pattern PR may be, for example, greater than or equal to 0.01 μm and may be less than or equal to 10 μm, but is not limited thereto. The thickness T21 may be the thickness of the mask pattern PR measured in a normal direction (a direction Z) of the substrate 10. A material of the mask pattern PR may include a suitable organic material, inorganic material, or combination thereof. The material of the mask pattern PR may include silicon, silicon carbon (Si—C), nickel monoxide (NiO), tin dioxide (SnO₂), titanium dioxide (TiO₂), an oxide, a polymer, other suitable materials, or combinations thereof, but is not limited thereto. The term “cover” referred to in the disclosure means that in a projection direction or in the normal direction (the direction Z) of the substrate 10, the mask pattern PR may overlap at least one part of the substrate 10. In other words, the mask pattern PR may directly contact the surface 10s1 of the substrate 10 or may not need to directly contact the surface 10s1 of the substrate 10.

Performing step (3): a connection element 20 is formed on the substrate 10.

In some embodiments, the connection element 20 may be formed by performing a deposition process, an electroless plating process, an electroplating process, or combinations thereof, but the disclosure is not limited thereto. In some embodiments, a material of the connection element 20 may include copper (Cu), titanium (Ti), titanium nitride (TiN), tantalum (Ta), tungsten (W), platinum (Pt), nickel (Ni), or combinations thereof, but the disclosure is not limited thereto. According to some embodiments, the connection element 20 is conformally formed on the substrate 10 and penetrating into the through hole T. For example, the connection element 20 may be disposed on at least one part of a surface of the substrate 10 and disposed in at least one part of the through hole T, but the disclosure is not limited thereto.

In some embodiments, before the connection element 20 is formed on the substrate 10, a seed layer (not shown) may be first formed on the substrate 10. In some embodiments, the seed layer may be formed by performing a suitable deposition process. For example, the seed layer may be formed by performing an electroless plating process, an electroplating process, an atomic layer deposition process (ALD), a physical vapor deposition process (PVD), a chemical vapor deposition process (CVD), a plasma enhanced chemical vapor deposition process (PECVD), or combinations thereof, but the disclosure is not limited thereto. The seed layer may include, for example, a stacked and multi-layered structure, but the disclosure is not limited thereto.

It is worth noting that, according to some embodiments, the partial surface 10s1 and the partial surface 10s2 of the substrate 10 are covered by the connection element 20.

Performing step (4): a filler material F is formed in an opening O of a dicing street region DS of the substrate 10.

In some embodiments, the filler material F may be formed by performing a suitable deposition process. For example, the filler material F may be formed by performing a coating process, an injection process, or a combination thereof, but the disclosure is not limited thereto. In some embodiments, the filler material F may include an organic material, a conductive material, a metal material, a heat dissipation material, or combinations thereof. For example, the filler material F may include a suitable polymer, metal, alloy, graphene, or silicon carbide composition, but the disclosure is not limited thereto. According to some embodiments, the filler material F fills the opening O. In some embodiments, the filler material F may further extend to a surface 10s3 of the substrate. The surface 10s3 is a surface connected to the surface 10s1 and the surface 10s2. In other embodiments, the filler material F may not extend to the surface 10s3 of the substrate 10. In some other embodiments, the filler material F may be further disposed on the surface 10s2 of the substrate 10, and the filler material F disposed on the surface 10s2 of the substrate 10 may at least partially overlap with the filler material F disposed on the surface 10s1 of the substrate 10.

Performing step (5): a thinning process is performed to expose the aforementioned surface 10s1 and surface 10s2 of the substrate 10 covered by the connection element 20 relative to the surface 10s1.

In detail, a part of the connection element 20 located on both sides of the substrate 10 may be removed by performing the thinning process. In some embodiments, the thinning process may include a grinding process, a chemical mechanical polishing process, a laser process, an etching process, a plasma process, or combinations thereof, but the disclosure is not limited thereto.

Performing step (6): a surface modification process is performed to form the surface 10s1 of the substrate 10, the surface 10s2 of the substrate 10, and a surface of the connection element 20 as rough surfaces. In some embodiments, the surface 10s1 of the substrate 10, the surface 10s2 of the substrate 10, the surface of the connection element 20, and the sidewall of the through hole T may have a surface roughness Rz that may be between 0.1 μm and 5 μm, for example, satisfying the following condition: 0.1 μm≤Rz≤5 μm. The surface roughness of the surface 10s1 of the substrate 10 and the surface roughness of the surface 10s2 of the substrate 10 are less than the surface roughness of the surface of the connection element 20, which may improve bonding force between film layers and avoid risk of glass cracking.

In some embodiments, the aforementioned rough surfaces may be formed by performing a wet etching process, where an etchant may be phosphoric acid, but the disclosure is not limited thereto. According to some embodiments, the roughness of the surface 10s1 of the substrate 10, the surface 10s2 of the substrate 10, and the surface of the connection element 20 may be between 0.1 nm and 5 μm, and the roughness of the surface 10s1 of the substrate 10 (or the roughness of the surface 10s2 of the substrate 10) and the roughness of the surface of the connection element 20 may be different from each other, but the disclosure is not limited thereto.

In some embodiments, a determination definition of roughness is to observe a side edge of each substrate 10 by using a scanning electron microscope (SEM) or a transmission electron microscope (TEM). If the difference between peaks and valleys of undulation on the side edge surface is 0.15 μm to 1 μm, it may be regarded as low roughness. By the SEM or TEM, the surface undulation condition of the side edge of each sub-perforated substrate may be observed under the same appropriate magnification, and the undulation condition may be compared by taking a unit length (for example, 10 μm), where “appropriate magnification” means that at least one surface may see at least 10 undulation peaks under the field of view of this magnification.

Performing step (7): a build-up structure 30 is formed on both sides of the substrate 10.

In detail, according to some embodiments, a forming method of the build-up structure 30 may include forming the build-up structure 30 on the surface 10s1 and the surface 10s2 of the substrate 10 respectively, or may simultaneously form the build-up structure 30 on the surface 10s1 and the surface 10s2 of the substrate 10. In other words, the build-up structure 30 includes a build-up structure 32 disposed on the surface 10s1 of the substrate 10 and a build-up structure 34 disposed on the surface 10s2 of the substrate 10 respectively. According to some embodiments, the build-up structure 32 contacts at least one part of the rough surface 10s1 of the substrate 10, and the build-up structure 34 contacts at least one part of the rough surface 10s2 of the substrate 10. Alternatively, the build-up structure 32 contacts at least one part of the filler material F.

According to some embodiments, the build-up structure 30 may be formed by forming a multi-layered insulation layer IL and a multi-layered conductive layer M alternately on the surface 10s1 and surface 10s2 of the substrate 10. In some embodiments, the multi-layered insulation layer IL and the multi-layered conductive layer M may each be formed through a suitable deposition process and patterning process, but the disclosure is not limited thereto. According to some embodiments, the build-up structure 32 includes a multi-layered insulation layer IL1 and a multi-layered conductive layer M1, and the build-up structure 34 includes a multi-layered insulation layer IL2 and a multi-layered conductive layer M2.

In detail, according to some embodiments, the build-up structure 30 may be a redistribution structure, which is configured to redistribute wiring and/or further enhance wiring fan-out area. Additionally, different electronic elements may be electrically connected to each other through the redistribution structure. For example, multiple electronic elements 2 to be introduced subsequently may be electrically connected to each other through the redistribution structure, or the redistribution structure serves as a substrate for electrical interface wiring between one connection and another connection. A purpose of the redistribution structure is to extend connections to wider spacing or redistribute connections to another connection with different spacing. In some embodiments, a material of the multi-layered insulation layer IL may include ajinomoto build-up film (ABF), polyimide (PI), photosensitive polyimide (PSPI), polybenzoxazole (PBO), epoxy, polymer, isophenylamine, silicon oxide (SiOₓ), silicon nitride (SiNₓ), or any combination thereof, but the disclosure is not limited thereto. In some embodiments, a material of the multi-layered conductive layer M may include copper (Cu), aluminum (Al), molybdenum (Mo), tungsten (W), gold (Au), chromium (Cr), nickel (Ni), platinum (Pt), titanium (Ti), silver (Ag), tantalum (Ta), metal nitride, other suitable conductive materials, or any combination thereof, but the disclosure is not limited thereto. According to some embodiments, after the insulation layer and the conductive layer are provided, a surface modification process may be performed to form rough surfaces on surfaces of the insulation layer and the conductive layer, where the roughness of the insulation layer is greater than the surface roughness of the substrate 10.

Performing step (8): the build-up structures 30 disposed on both sides of the substrate 10 is simultaneously cut.

In some embodiments, a cutting process may be performed to remove a part of the build-up structure 30 formed on the substrate 10 to form a recess P1 and a recess P2. The cutting process may include a laser cutting process, a dicing blade cutting process, or a combination thereof, but the disclosure is not limited thereto.

In some embodiments, after the part of the build-up structure 30 formed on the substrate 10 is removed, the recess P1 may expose a part of a surface of the filler material F and the recess P2 may expose a part of the surface 10s2. In detail, the build-up structure 32 and the build-up structure 34 on both sides of the substrate 10 are simultaneously cut. In some embodiments, after the laser process is performed on both sides of the substrate 10, a groove R1 and a groove R2 may be respectively formed in the build-up structure 30 located on both sides of the substrate 10. The groove R1 and the groove R2 at least partially overlap in the normal direction (the direction Z) of the substrate 10, and overlap the opening O in the normal direction (the direction Z) of the substrate 10. According to some embodiments, a depth d1 of the groove R1 is substantially equal to a depth d2 of the groove R2, but the disclosure is not limited thereto. Through the aforementioned design, disposing the filler material F in the opening O and simultaneously cutting the build-up structure 30 at a position corresponding to the opening O may reduce the cracking risk of the substrate 10. In some embodiments, simultaneously cutting the build-up structure 30 after electronic element 2a is disposed on the build-up structure 30, but it is not limited to.

Performing step (9): the substrate 10 is cut in the dicing street region DS to obtain an electronic device 1a.

According to some embodiments, the cutting process performed in the dicing street region DS may include performing the laser process on the surface 10s1 and surface 10s2 of the substrate 10 corresponding to the dicing street region DS. In some embodiments, before the cutting process is performed, a laser induced treatment may be performed on a part corresponding to the dicing street region DS, but the disclosure is not limited thereto. Furthermore, in the process of cutting the substrate 10, the part of the build-up structure 30 may be further removed to expose the partial surface 10s1 and the partial surface 10s2 of the substrate 10.

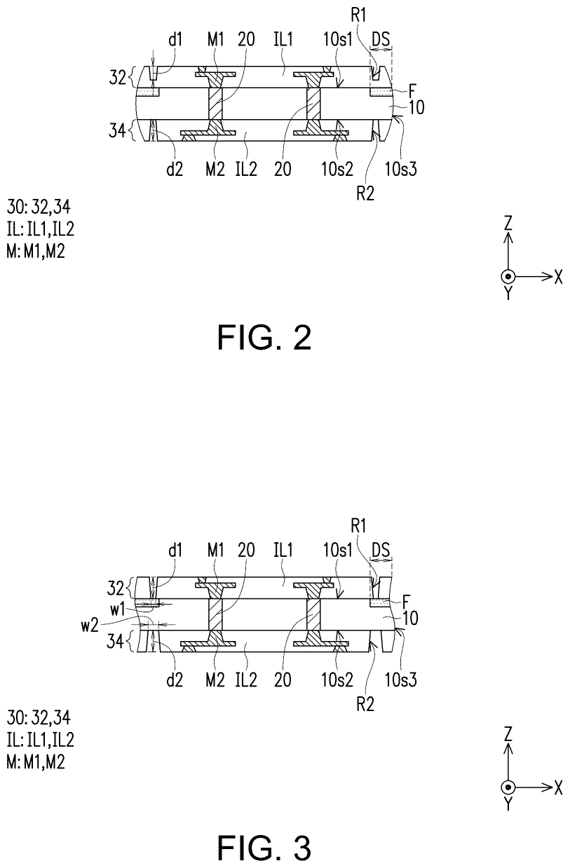

FIG. 2 is a schematic view of an intermediate process of a manufacturing method of an electronic device according to an embodiment of the disclosure. It should be noted that the embodiment of FIG. 2 may adopt the reference numerals of the elements and partial content of the embodiment of FIG. 1, where the same or similar reference numerals are used to represent the same or similar elements, and descriptions of the same technical content are omitted.

Please refer to FIG. 2. According to some embodiments, before the aforementioned step (8) (performing the laser process on both sides of the substrate 10) is performed, the stress sustained on one side of the surface 10s2 of the substrate 10 is greater than the stress sustained on one side of the surface 10s1 of the substrate 10, a reason for which may be, for example, that a proportion of the conductive layer M in the build-up structure 34 is greater than a proportion of the conductive layer M in the build-up structure 32, but the disclosure is not limited thereto.

After the aforementioned step (8) (performing the laser process on both sides of the substrate 10) is performed, the groove R1 and the groove R2 are respectively formed in the build-up structure 30 located on both sides of the substrate 10. Due to different metal proportions of the build-up structure 32 and the build-up structure 34, the depth d1 of the groove R1 is designed to be different from the depth d2 of the groove R2. For example, the depth d1 of the groove R1 is designed to be smaller than the depth d2 of the groove R2. Through this design of this embodiment, the stresses generated on both sides of the substrate 10 may be matched, so as to reduce the possibility of the electronic device 1a generating warpage or reduce the cracking risk of the substrate 10.

Additionally, according to some embodiments, after the substrate 10 is cut in the dicing street region DS, a side surface 10s3 of the substrate 10 may have an arcuate shape, for example, an outwardly convex arcuate shape, but the disclosure is not limited thereto.

FIG. 3 is a schematic view of an intermediate process of a manufacturing method of an electronic device according to another embodiment of the disclosure. It should be noted that the embodiment of FIG. 3 may adopt the reference numerals of the elements and partial content of the embodiments of FIG. 1 and FIG. 2, where the same or similar reference numerals are used to represent the same or similar elements, and descriptions of the same technical content are omitted.

Please refer to FIG. 3. Similarly, according to some embodiments, before the aforementioned step (8) is performed, the stress sustained on one side of the surface 10s2 of the substrate 10 is greater than the stress sustained on one side of the surface 10s1 of the substrate 10.

After the aforementioned step (8) is performed, due to different metal proportions of the build-up structure 32 and the build-up structure 34, a width w1 of the groove R1 is designed to be different from a width w2 of the groove R2. For example, the width w1 of the groove R1 is designed to be smaller than the width w2 of the groove R2. Through this design of this embodiment, the stresses generated on both sides of the substrate 10 may be matched, so as to reduce the possibility of the electronic device 1a generating warpage.

Additionally, according to some embodiments, after the substrate 10 is cut in the dicing street region DS, the side surface 10s3 of the substrate 10 may have an arcuate shape, for example, an inwardly concave arcuate shape, but the disclosure is not limited thereto.

FIG. 4 is a schematic cross-sectional view of an electronic device according to an embodiment of the disclosure. It should be noted that the embodiment of FIG. 4 may adopt the reference numerals of the elements and partial content of the embodiment of FIG. 1, where the same or similar reference numerals are used to represent the same or similar elements, and descriptions of the same technical content are omitted.

Please refer to FIG. 4. According to some embodiments, an electronic device 1b may include a substrate 10, a through hole T, a connection element 20, and a build-up structure 30.

According to some embodiments, the substrate 10 is a glass substrate. In some embodiments, a thermal expansion coefficient of the substrate 10 may be greater than or equal to 3 ppm/° C. and less than or equal to 15 ppm/° C., and a transmittance of the substrate 10 for light may be greater than or equal to 75%, where the light may include white light, UV light, and so on, but the disclosure is not limited thereto. In some embodiments, the transmittance of the substrate 10 for light with a wavelength of 280 nm to 400 nm is 75% to 99.9%. In some embodiments, the substrate 10 may include silicon dioxide (SiO₂), boron trioxide (B₂O₃), aluminum trioxide (Al₂O₃), metal oxides, combinations of the above, or other suitable materials, but is not limited thereto. For example, a glass composition forming the glass substrate may include 50 wt % to 90 wt % of SiO₂, 3 wt % to 15 wt % of B₂O₃, 0.5 wt % to 25 wt % of Al₂O₃, less than or equal to 20 wt % of other metal oxides such as an oxide of alkali metal and an oxide of alkaline earth metal. Thereby, it is beneficial to enhance the stiffness of the substrate 10, but is not limited thereto.

The through hole T, for example, penetrates the substrate 10. In detail, according to some embodiments, the through hole T penetrates from the surface 10s1 of the substrate 10 to the surface 10s2. In some embodiments, the through hole T may have a dumbbell shape or a hourglass shape, but the disclosure is not limited thereto. For the remaining description of the through hole T, reference may be made to the aforementioned embodiments, which is not repeated here.

The connection element 20 is, for example, penetrating into the through hole T. According to some embodiments, the connection element 20 may be disposed on at least one part of the surface 10s1 and at least one part of the surface 10s2 of the substrate 10, and penetrates into the through hole T, for example, the through hole T is filled, but the disclosure is not limited thereto. Additionally, according to some embodiments, a seed layer S may also be formed in the through hole T. The seed layer S may be disposed on the at least one part of the surface 10s1 and at least one part of the surface 10s2 of the substrate 10, and disposed in at least one part of the through hole T, but the disclosure is not limited thereto. For the remaining description of the connection element 20 and the seed layer S, reference may be made to the aforementioned embodiments, which is not repeated here.

The build-up structure 30 is, for example, disposed on the substrate 10 and is electrically connected to the connection element 20. According to some embodiments, the build-up structure 30 includes a build-up structure 32 and a build-up structure 34. The build-up structure 32 is, for example, disposed on the surface 10s1 of the substrate 10 and at least partially overlaps the through hole T. In some embodiments, the build-up structure 32 includes a multi-layered insulation layer IL1 and a multi-layered conductive layer M1. The build-up structure 34 is, for example, disposed on the surface 10s2 of the substrate 10 and at least partially overlaps the through hole T. In some embodiments, the build-up structure 34 includes a multi-layered insulation layer IL2 and a multi-layered conductive layer M2. The materials of the multi-layered insulation layer IL2 and the multi-layered conductive layer M2 may be the same as or similar to the materials of the multi-layered insulation layer IL1 and the multi-layered conductive layer M1, respectively.

According to some embodiments, the build-up structure 32 and the build-up structure 34 are each redistribution structures, which may be configured to redistribute wiring and/or further enhance wiring fan-out area. The purpose of disposing redistribution structures is to extend connections to wider pitches or redistribute connections to another connection with different pitches. In this way, the electronic elements 2 that are the same as or different from each other may be disposed on the build-up structure 32 and electrically connected thereto, and the circuit board CB may be disposed on the build-up structure 34 and electrically connected thereto, so that the electronic elements 2 may be electrically connected to the circuit board CB through the build-up structure 32 and the build-up structure 34.

For the remaining description of the build-up structure 30, reference may be made to the above embodiments, which is not repeated here.

According to some embodiments, the electronic device 1b further includes multiple electronic elements 2. Each of the electronic elements 2 may have the same function or different functions. According to some embodiments, the electronic device 1b may be a 2.5D packaging structure that horizontally places the electronic elements 2 side by side, but the disclosure is not limited thereto.

According to some embodiments, the electronic device 1b includes two electronic elements 2a and 2b. The electronic element 2a may be, for example, a high bandwidth memory (HBM) and may be electrically connected to the conductive layer M1 in the build-up structure 32 through a pad PAD and a connection unit CU1. A material of the pad PAD and the connection unit CU1 may include copper, nickel, tin, silver, gold, gallium, or other suitable materials, but the disclosure is not limited thereto. The electronic element 2b may be, for example, a graphic processing unit (GPU) and may be electrically connected to the conductive layer M1 in the build-up structure 32 through the connection unit CU1. However, the disclosure is not limited to the types of the electronic elements.

According to some embodiments, the electronic device 1b further includes an adhesive layer UF1, a circuit board CB, an adhesive layer UF2, and a packaging layer PL.

The adhesive layer UF1 is, for example, disposed between the electronic elements 2 and the build-up structure 32. In detail, the adhesive layer UF1 may directly contact the active surfaces of the elements 2 and fill a space between adjacent two connection units CU1. A material of the adhesive layer UF1 may include a suitable inorganic material or organic material, but the disclosure is not limited thereto. In some embodiments, the adhesive layer UF1 may include adhesive configured to fix the electronic elements 2.

The circuit board CB may be, for example, configured to carry the electronic elements 2 described above. According to some embodiments, the circuit board CB may be electrically connected to the electronic elements 2 through a connection unit CU2 and the build-up structure 30.

The adhesive layer UF2 is, for example, disposed between the circuit board CB and the build-up structure 34. According to some embodiments, the adhesive layer UF2 may fill a space between adjacent two connection elements CU2. A material of the adhesive layer UF2 may be the same as or similar to the material of the adhesive layer UF1, which is not repeated here.

The packaging layer PL, for example, surrounds the electronic elements 2. In some embodiments, the packaging layer PL may expose back surfaces of the electronic elements 2 to facilitate heat dissipation of the electronic device 1b. A material of the packaging layer PL may include epoxy molding compound (EMC), but the disclosure is not limited thereto. According to some embodiments, the build-up structure 32 exposes the rough surface 10s1 of the substrate 10. Therefore, the packaging layer PL may contact at least another part of the rough surface 10s1 of the substrate 10, so that the adhesion between the packaging layer PL and the substrate 10 may be improved.

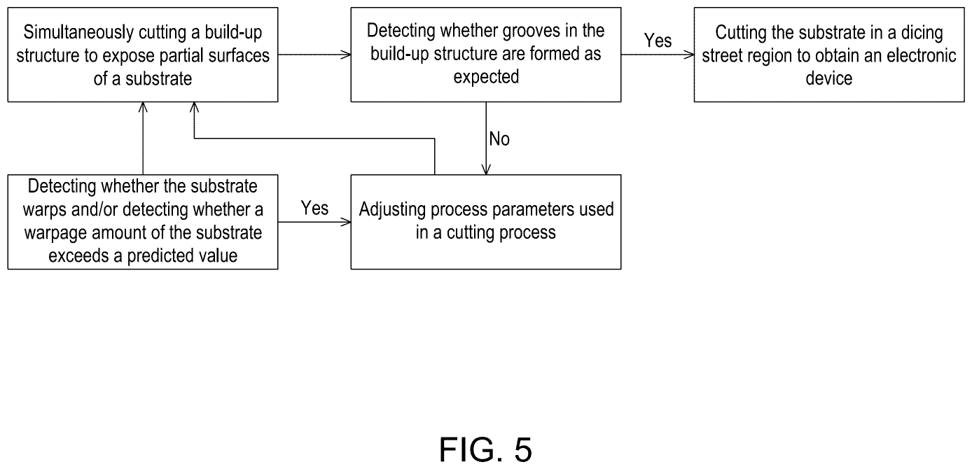

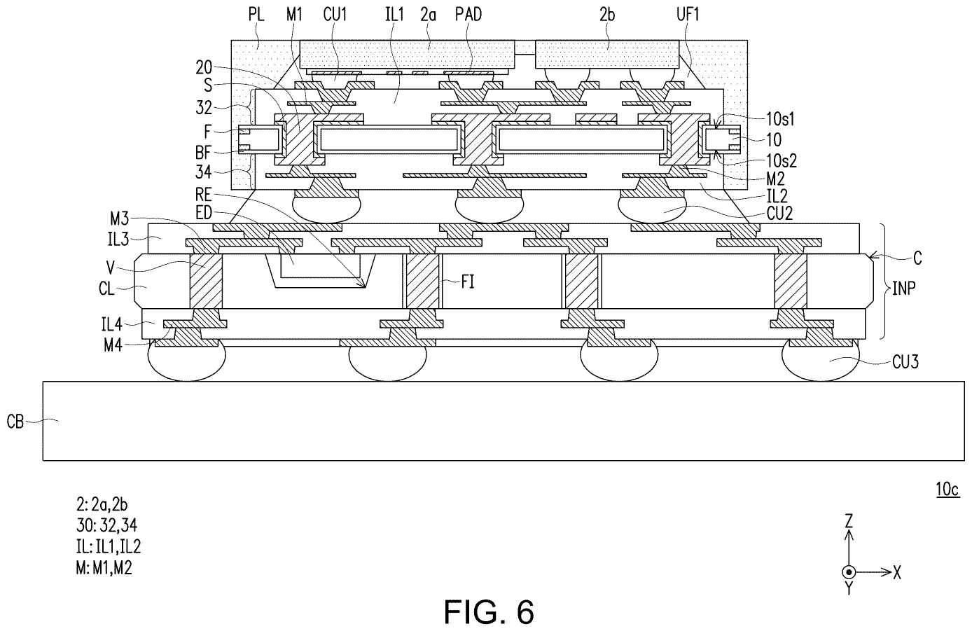

FIG. 5 is a flow chart of a manufacturing method of an electronic device according to an embodiment of the disclosure. It should be noted that the embodiment of FIG. 5 may adopt the reference numerals of the elements and partial content of the embodiment of FIG. 1, where the same or similar reference numerals are used to represent the same or similar elements, and the description of the same technical content is omitted.

Please refer to FIG. 5. According to some embodiments, in the process of performing step (8) (simultaneously cutting the build-up structure 30 to expose the part of the surface 10s1 and/or the part of the surface 10s2 of the substrate 10), a monitoring device (not shown) may be used to detect whether the substrate 10 warps and/or detect whether the warpage amount of the substrate 10 exceeds a predicted value. If yes, an alarm device (not shown) may be used to alert the operator performing the process, so that the operator adjusts the process parameters used in the cutting process.

Additionally, after step (8) (simultaneously cutting the build-up structure 30 to expose the part of the surface 10s1 and/or the part of the surface 10s2 of the substrate 10) is performed, a detection device (not shown) may be used to detect whether the groove R1 and/or the groove R2 in the build-up structure 30 are formed as expected. If not, the process parameters used in the cutting process may be adjusted before step (9) (cutting the substrate 10 in the dicing street region DS to obtain the electronic device) is performed.

FIG. 6 is a schematic cross-sectional view of an electronic device according to another embodiment of the disclosure. It should be noted that the embodiment of FIG. 6 may adopt the reference numerals of the elements and partial content of the embodiment of FIG. 4, where the same or similar reference numerals are used to represent the same or similar elements, and the description of the same technical content is omitted.

Please refer to FIG. 6. According to some embodiments, an electronic device 1c may include a substrate 10, a through hole T, a connection element 20, a build-up structure 30, and a middleware INP. The detailed descriptions of the substrate 10, the through hole T, the connection element 20, and the build-up structure 30 may refer to the aforementioned embodiments, but the disclosure is not limited thereto.

The middleware INP may include, for example, a core layer CL, a perforation V, an insulation layer IL3, a conductive layer M3, an insulation layer IL4, and a conductive layer M4. A material of the core layer CL may be, for example, silicon, glass, or an organic material. In some embodiments, an edge of the core layer CL may have a chamfer C, but the disclosure is not limited thereto. The perforation V is, for example, provided in plurality and penetrates the core layer CL. In some embodiments, if the material of the core layer CL is silicon, the perforation V may be referred to as silicon perforation, but the disclosure is not limited thereto. In some embodiments, the perforation V may further include a filler material FI, but the disclosure is not limited thereto. The insulation layer IL3 and the conductive layer M3 are, for example, disposed above the core layer CL and located between the core layer CL and the build-up structure 34 in the direction Z, where the insulation layer IL3 and the conductive layer M3 may be combined into a redistribution structure, so that the conductive layer M2 in the build-up structure 34 may be electrically connected to the perforation V of the core layer CL. The insulation layer IL4 and the conductive layer M4 are, for example, disposed below the core layer CL and located between the core layer CL and the circuit board CB in the direction Z, where the insulation layer IL4 and the conductive layer M4 may be combined into a redistribution structure, so that the circuit board CB may be electrically connected to the perforation V of the core layer CL through a connection unit CU3. In this way, according to some embodiments, the electronic elements 2 may be electrically connected to the circuit board CB through the middleware INP.

According to some embodiments, the middleware INP may include an embedded die ED disposed in a groove RE of the core layer CL. The embedded die ED may be, for example, electrically connected to the perforation V of the core layer CL through the conductive layer M3.

According to some embodiments, the electronic device 1c may further include a buffer layer BF. The buffer layer BF is, for example, disposed on the substrate 10 and may cover the surface 10s1, surface 10s2, and surface 10s3 of the substrate 10. In this way, disposing the buffer layer BF is beneficial to reduce the probability of the substrate 10 generating microcracks, but the disclosure is not limited thereto. The buffer layer BF may include single layer or multilayer stacking, for example, and may be formed by the electroplating process, the electroless plating process, the physical vapor deposition process, or other suitable processes, for example. In some embodiments, the toughness of buffer layer BF may be 0.1 kJ/m² to 100 kJ/m². A material of the buffer layer may, for example, include an organic material or an inorganic material. For example, the buffer layer BF may include polyimide (PI) resin, parylene material, benzocyclobutene (BCB), epoxy, polycarbonate (PC), polyethylene terephthalate (PET), polyethylene naphthalate (PEN), an oxide, other suitable materials, or combinations of the aforementioned materials, but the disclosure is not limited thereto. For example, a stacking method of the buffer layer BF may be organic-inorganic-organic, organic-organic-organic, and organic-organic-inorganic. In some embodiments, in the cross-sectional view shown in FIG. 6, a thickness of the buffer layer BF may be between 0.01 μm and 10 μm. The aforementioned thickness of the buffer layer BF may refer to the maximum thickness of the buffer layer BF on the surface 10s1 of the substrate 10 along a vertical direction (the direction Z), or may refer to the thickness of the buffer layer BF on the hole wall of through hole T along a horizontal direction (for example, a horizontal direction X or direction Y). In some embodiments, a ratio of the thickness of the buffer layer BF to a hole diameter of the through hole T may be 0.02 to 0.2, but the disclosure is not limited thereto.

In summary, in the manufacturing method of the electronic device provided by some embodiments of the disclosure, by simultaneously cutting the build-up structure located on both sides of the substrate, the possibility of technical problems such as warpage and/or cracking of the substrate due to stress mismatch may be reduced, thereby improving the yield and/or reliability of the manufactured electronic device.

What is claimed is:

1. A manufacturing method of an electronic device, comprising:
providing a substrate, the substrate having a first surface and a second surface;
forming a through hole penetrating the substrate;
forming a build-up structure on the first surface and the second surface of the substrate; and
simultaneously cutting the build-up structure disposed on the first surface and the second surface, so that the build-up structure forms a first groove and a second groove respectively.

2. The manufacturing method of an electronic device according to claim 1, further comprising cutting the substrate in a dicing street region to obtain the electronic device after a partial surface of the first surface or a partial surface of the second surface of the substrate is cut to be exposed.

3. The manufacturing method of an electronic device according to claim 1, wherein the first groove and the second groove at least partially overlap in a normal direction of the substrate.

4. The manufacturing method of an electronic device according to claim 3, wherein in the normal direction of the substrate, a depth of the first groove and a depth of the second groove are different.

5. The manufacturing method of an electronic device according to claim 3, wherein in a direction perpendicular to the normal direction of the substrate, a width of the first groove and a width of the second groove are different.

6. The manufacturing method of an electronic device according to claim 2, wherein the dicing street region comprises an opening, and the opening comprises a filler material.

7. The manufacturing method of an electronic device according to claim 1, further comprising forming a connection element on the substrate and penetrating into the through hole.

8. The manufacturing method of an electronic device according to claim 7, further comprising performing a thinning process to remove a part of the connection element located on the both sides of the substrate.

9. The manufacturing method of an electronic device according to claim 8, further comprising performing a surface modification process to form the surface of the substrate and a surface of the connection element as rough surfaces, and the build-up structure exposes at least a part of the rough surface of the substrate.

10. The manufacturing method of an electronic device according to claim 9, wherein a roughness of the surface of the substrate and a roughness of the surface of the connection element are different.

11. The manufacturing method of an electronic device according to claim 1, wherein in a process of simultaneously cutting the build-up structure to expose the partial surface of the substrate, whether the substrate warps and/or detecting whether a warpage amount of the substrate exceeds a predicted value is detected, and if the substrate warps and/or the warpage amount of the substrate exceeds the predicted value, then process parameters used in the process of cutting the build-up structure are adjusted.

12. The manufacturing method of an electronic device according to claim 3, wherein after the build-up structure to expose the partial surface of the substrate is simultaneously cut, whether the first groove and the second groove in the build-up structure are formed as expected is detected, and if the first groove and/or the second groove have defects, then process parameters used in the process of cutting the build-up structure are adjusted.

13. The manufacturing method of an electronic device according to claim 7, wherein the through hole further comprises a seed layer formed therein.

14. The manufacturing method of an electronic device according to claim 6, wherein the opening is located on the both sides of the substrate.

15. An electronic device, comprising:
a substrate;
a through hole, penetrating the substrate;
a connection element, disposed in the through hole; and
a build-up structure, disposed on both sides of the substrate and electrically connected to the connection element,
wherein surfaces located on the both sides of the substrate are rough surfaces, a roughness of the rough surfaces is between 0.1 μm and 5 μm, and the build-up structure exposes at least one part of the rough surfaces.

16. The electronic device according to claim 15, further comprising:
a plurality of electronic elements electrically connected to the build-up structure.

17. The electronic device according to claim 16, further comprising:
a packaging layer, surrounding the plurality of electronic elements, wherein the packaging layer contacts the at least one part of the rough surfaces.

18. The electronic device according to claim 15, further comprising:
a seed layer, disposed in at least one part of the through hole.

19. The electronic device according to claim 15, wherein the substrate is a glass substrate.
